(19) United States
(12) Patent Application Publication
(10) Pub. No.: US 2026/0231446 A1
(43) Pub. Date: Aug. 6, 2026

(54) Capacitor, Memory Circuitry, And Methods Used In Forming Memory Circuitry

(71) Applicant: Micron Technology, Inc., Boise, ID (US)

(72) Inventors: Akie Shimamura, Boise, ID (US); Dojun Kim, Boise, ID (US); Yoshitaka Nakamura, Boise, ID (US)

(73) Assignee: Micron Technology, Inc., Boise, ID (US)

(21) Appl. No.: 19/045,949

(22) Filed: Feb. 5, 2025

(51) Int. Cl. H10D 1/68; H10B 12/00

(52) U.S. Cl. CPC H10D 1/716; H10B 12/315; H10B 12/50

(57) ABSTRACT

A capacitor comprises a first capacitor electrode, a second capacitor electrode, and a capacitor insulator between the first and second capacitor electrodes. The storage-node electrode comprises a container-like shape comprising an axis. In a cross-section that is through and elongated along the axis, the storage-node electrode comprises a radially-outermost conductive surface comprising a first conductive material and a radially-innermost conductive surface comprising a second conductive material that is of different composition from that of the first conductive material. Other embodiments, including memory circuitry and method are disclosed.

### TECHNICAL FIELD

Embodiments disclosed herein pertain to capacitors, to memory circuitry, and to methods used in forming memory circuitry

### BACKGROUND

Memory is one type of integrated circuitry and is used in computer systems for storing data. Memory may be fabricated in one or more arrays of individual memory cells. Memory cells may be written to, or read from, using digitlines (which may also be referred to as bitlines, data lines, or sense lines) and access lines (which may also be referred to as wordlines). The sense lines may conductively interconnect memory cells along columns of the array, and the access lines may conductively interconnect memory cells along rows of the array. Each memory cell may be uniquely addressed through the combination of a sense line and an access line.

Memory cells may be volatile, semi-volatile, or non-volatile. Non-volatile memory cells can store data for extended periods of time in the absence of power. Non-volatile memory is conventionally specified to be memory having a retention time of at least about 10 years. Volatile memory dissipates and is therefore refreshed/rewritten to maintain data storage. Volatile memory may have a retention time of milliseconds or less. Regardless, memory cells are configured to retain or store memory in at least two different selectable states. In a binary system, the states are considered as either a “0” or a “1”. In other systems, at least some individual memory cells may be configured to store more than two levels or states of information.

Memory cells may be arranged or arrayed in several manners including, for example, in a vertical stack (e.g., along a vertical z-direction) comprising a three-dimensional (3D) memory array region having horizontal tiers in which individual memory cells are received (e.g., arrayed in horizontal x and y directions). The stack in the 3D memory array region comprises vertically-alternating insulative tiers and conductive tiers (e.g., as part of memory-cell tiers) that extend into a stair-step region. The stair-step region includes individual “stairs” (alternately termed “steps” or “stair-steps”) that define contact regions of conductive lines of individual of the conductive tiers to which vertical conductive vias can contact to provide electrical access to/from those conductive lines.

A capacitor is one type of electronic component that may be used in a memory cell. A capacitor has two electrical conductors separated by electrically insulating material. Energy as an electric field may be electrostatically stored within such material. Depending on composition of the insulator material, that stored field will be volatile or non-volatile. For example, a capacitor insulator material including only SiO₂ will be volatile. One type of non-volatile capacitor is a ferroelectric capacitor which has ferroelectric material as at least part of the insulating material. Ferroelectric materials are characterized by having two stable polarized states and thereby can comprise programmable material of a capacitor and/or memory cell. Other programmable materials may be used as a capacitor insulator to render capacitors non-volatile.

A field effect transistor is another type of electronic component that may be used in a memory cell. These transistors comprise a pair of conductive source/drain regions having a semiconductive channel region there-between. A conductive gate is adjacent the channel region and separated therefrom by a thin gate insulator. Application of a suitable voltage to the gate allows current to flow from one of the source/drain regions to the other through the channel region. When the voltage is removed from the gate, current is largely prevented from flowing through the channel region. Field effect transistors may also include additional structure, for example a reversibly programmable charge-storage region as part of the gate construction between the gate insulator and the conductive gate. Regardless, the gate insulator may be programmable, for example being ferroelectric.

Capacitors and field effect transistors can of course be used in other integrated circuitry not comprising memory circuitry.

### BRIEF DESCRIPTION OF THE DRAWINGS

FIG. 1 is a diagrammatic schematic of a DRAM memory array and peripheral circuitry in accordance with the prior art and in accordance with an embodiment of the invention.

FIG. 2 is an enlargement of a portion of FIG. 1.

FIGS. 3-11 are diagrammatic sectional views of a construction in accordance with embodiments of the invention.

FIGS. 12-25 are diagrammatic sequential sectional and/or enlarged views of the construction of FIGS. 3-11, or portions thereof or alternate and/or additional embodiments, in process in accordance with some embodiments of the invention.

### DETAILED DESCRIPTION OF EXAMPLE EMBODIMENTS

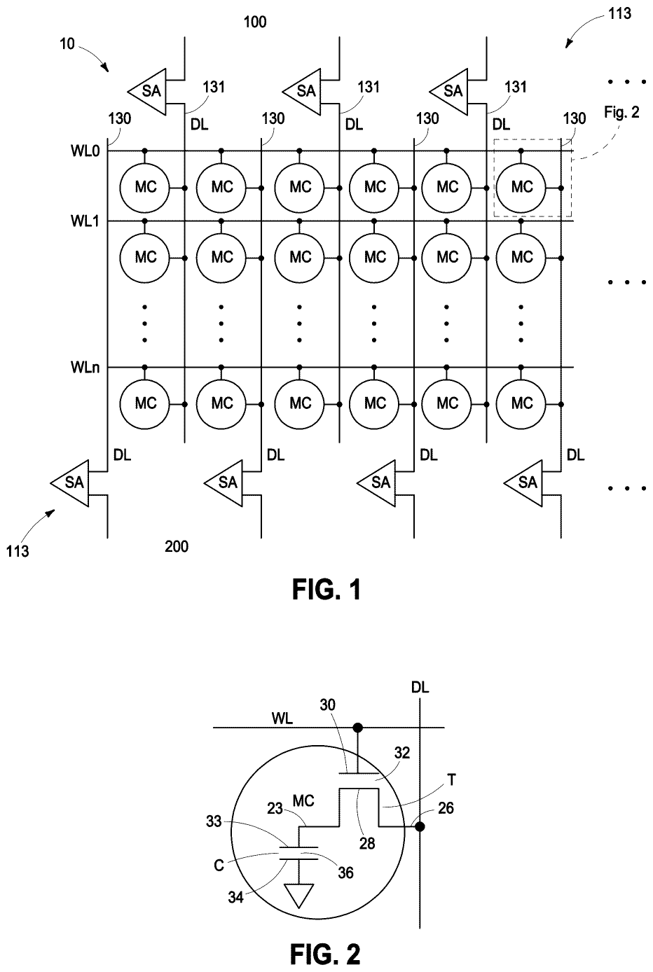

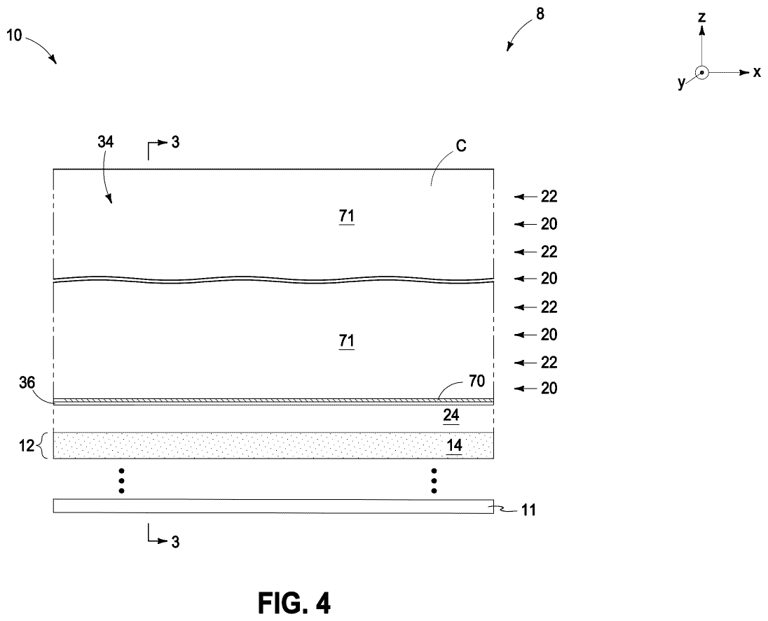

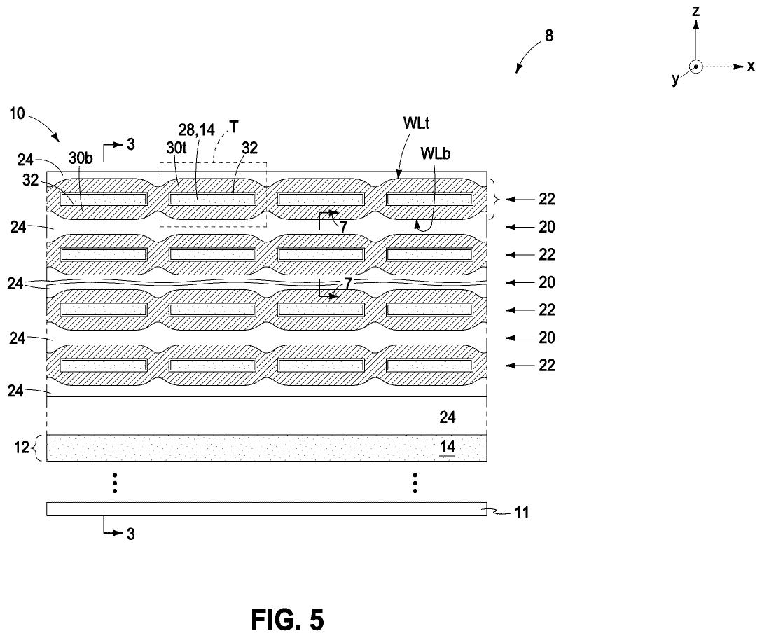

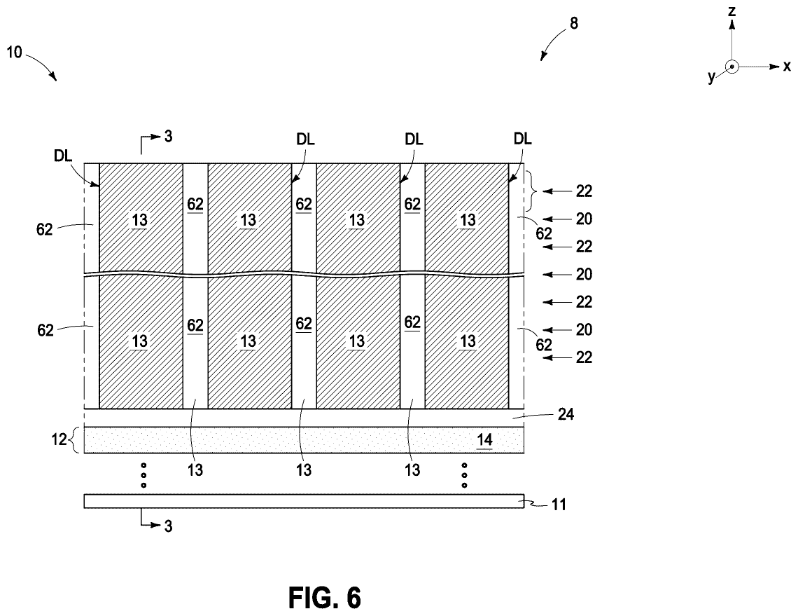

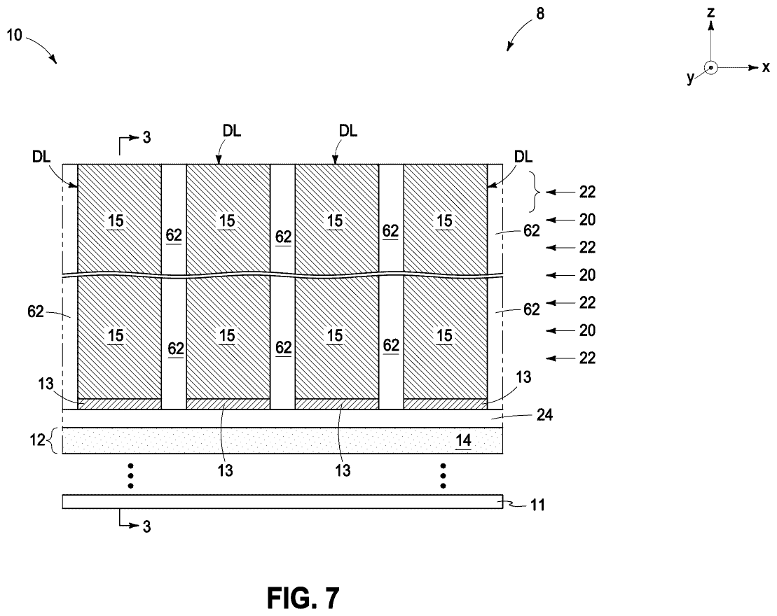

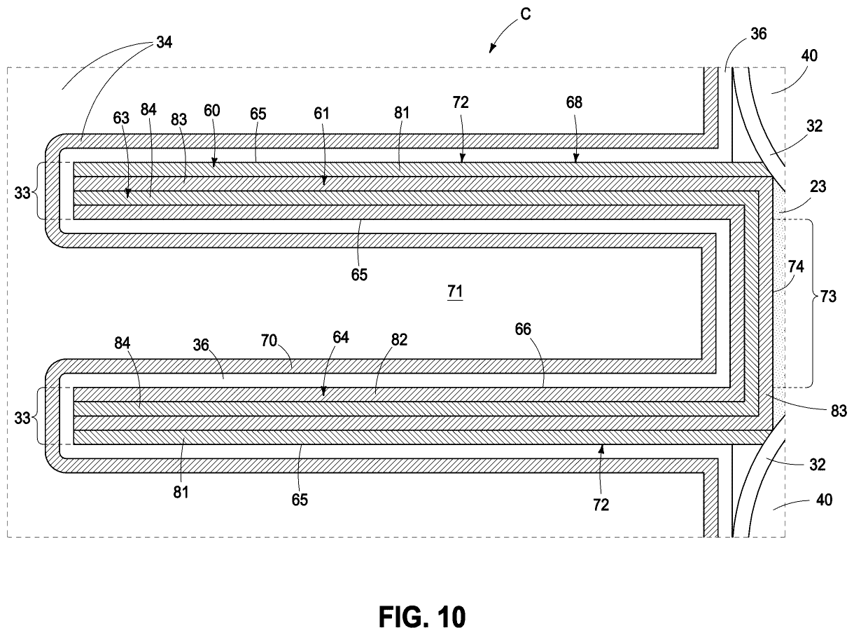

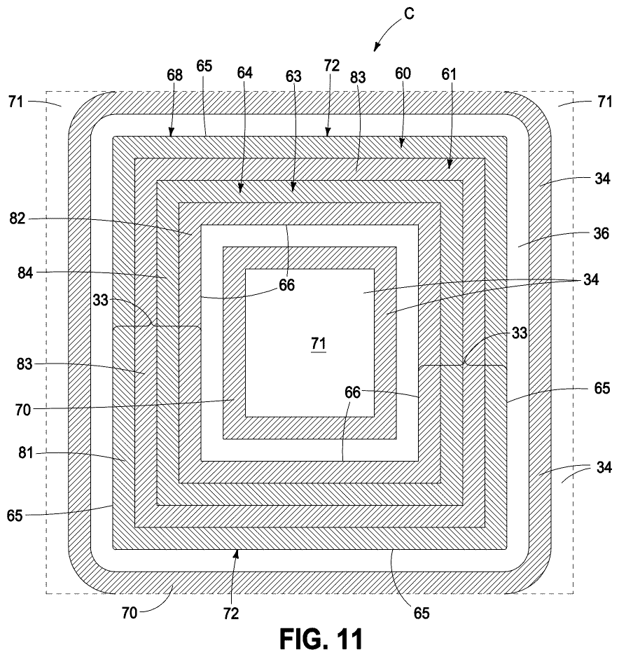

Embodiments of the invention encompass a capacitor and memory circuitry (e.g., DRAM) comprising vertically-stacked memory cells individually comprising a horizontal transistor and a capacitor electrically coupled therewith. Example embodiments of the invention also encompass methods used in forming such memory circuitry. Example structure embodiments are first described with reference to FIGS. 1-11.

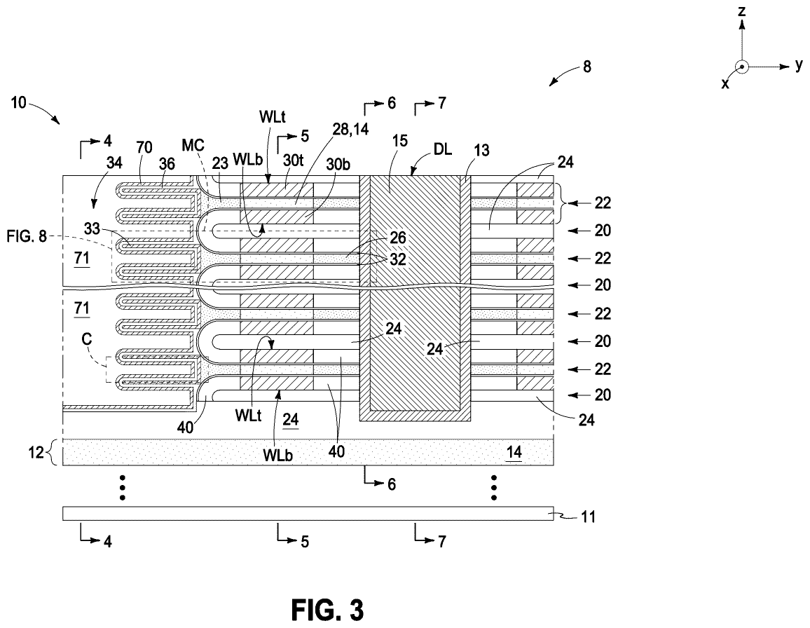

One example prior art schematic diagram of DRAM circuitry, and in accordance with an embodiment of the invention, is shown in FIGS. 1 and 2. FIG. 2 shows example memory cells MC individually comprising a transistor T and a capacitor C. One electrode of capacitor C is directly electrically coupled to a suitable potential (e.g., ground) and the other capacitor electrode is contacted with or comprises one of the source/drain regions of transistor T. The other source/drain region of transistor T is directly electrically coupled with a digitline/sense line 130 or 131 (also individually designated as DL). The gate of transistor T is directly electrically coupled with (e.g., comprises part thereof) a wordline/access line WL. FIG. 1 shows digitlines 130 and 131 extending from one of opposite sides 100 and 200 of a memory array area 10 into a peripheral circuitry area 113 that is aside memory array area 10. Digitlines 130 and 131 individually directly electrically couple with a sense amp SA on opposite sides 100 and 200 of array area 10 within peripheral circuitry area 113. Sense amps SA could be on only one side or all directly above or directly below memory array area 10. Non-schematic structure embodiments as shown herein in FIG. 3+ have the wordlines/access lines running horizontally and the digitlines/sense lines running vertically.

Referring to FIGS. 3-11, an example fragment of a substrate construction 8 comprising array or array area 10 has been fabricated relative to a base substrate 11. Substrate 11 comprises any one or more of conductive/conductor/conducting, semiconductive/semiconductor/semiconducting, and insulative/insulator/insulating (i.e., electrically herein) materials. Materials may be aside, elevationally inward, or elevationally outward of the FIGS. 3-11—depicted materials. For example, other partially or wholly fabricated components of integrated circuitry may be provided somewhere above, about, or within base substrate 11. Control and/or other peripheral circuitry for operating components within a memory array may also be fabricated and may or may not be wholly or partially within a memory array or sub-array. Further, multiple sub-arrays may also be fabricated and operated independently, in tandem, or otherwise relative one another. As used in this document, a “sub-array” may also be considered as an array. Example construction 8 comprises a semiconductor substrate 12 (e.g., monocrystalline silicon 14) having insulative material 24 there-above (e.g., silicon dioxide and/or silicon nitride).

Example memory circuitry (e.g., that of or comprising construction 8) comprises vertically-alternating tiers 20, 22 (e.g., along example direction z) of insulative material 24 (e.g., silicon dioxide and/or silicon nitride) and vertically-stacked memory cells MC, respectively. Memory cells MC individually comprise a horizontal transistor T and a capacitor C electrically coupled (e.g., directly) therewith. Example horizontal transistor T comprises a gate 30* (e.g., conductive metal material) that is part of one of a plurality of horizontal conductive access lines WL* that individually directly electrically couple together multiple of gates 30* of different ones of horizontal transistors T that are in the same memory-cell tier 22 (an * being used as a suffix to be inclusive of all such same-numerically-designated structures or portions thereof that may or may not have other suffixes). Gate 30* comprises a top gate 30t and a bottom gate 30b having a channel region 28 vertically there-between. Top gate 30t is part of one of a plurality of top horizontal access lines WLt and bottom gate 30b is part of one of a plurality of bottom horizontal access lines WLb. Individual top and bottom access lines WLt and WLb, respectively, are horizontally elongated in a horizontal x-direction and are laterally spaced from one another in a horizontal y-direction that is perpendicular to x-direction. Insulative material 24 of insulative tiers 20 is vertically between top access line WLt and bottom access line WLb of immediately-vertically-adjacent the memory-cell tiers 22 (there being no other such noun [tier] between those that are immediately-adjacent one another).

Example horizontal transistor T comprises a first source/drain region 23 (e.g., conductively-doped silicon), a second source/drain region 26 (e.g., conductively-doped silicon), with channel region 28 being horizontally there-between. Regions 23 and 26 of different immediately-horizontally-adjacent memory cells MC into and out of the plane of the page upon which FIG. 3 lies in a common memory-cell tier 22 (e.g., in the x-direction) may be isolated relative one another by insulative material (not shown). A gate insulator 32 (e.g., dielectric or ferroelectric) is vertically between each of the respective top and bottom gates 30t and 30b and channel region 28. An example insulator material 40 (e.g., silicon nitride) is laterally against lateral sides/edges of gates 30*.

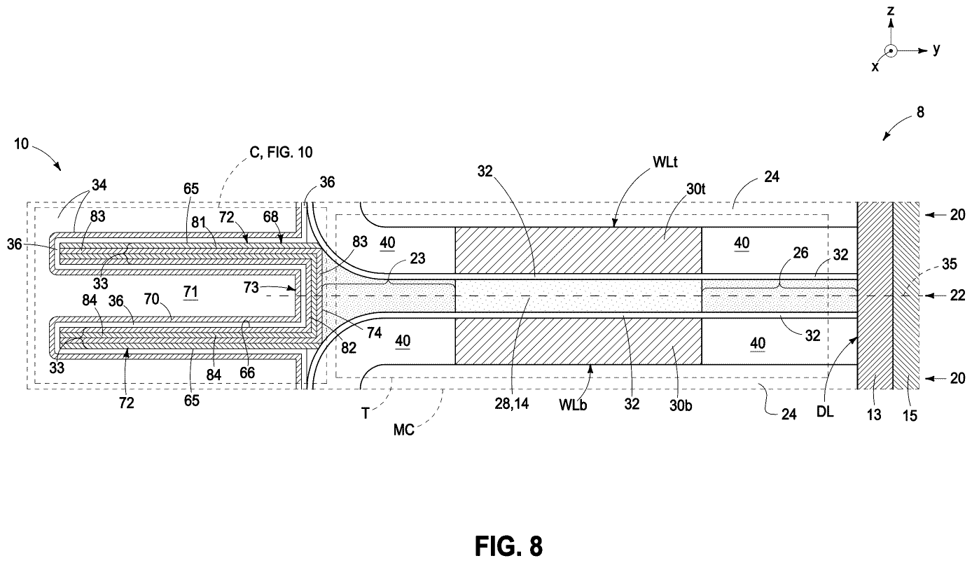

Digitlines DL (e.g., comprising conductive materials 13 and 15) extend through vertically-alternating tiers 20 and 22. Conductively-doped semiconductive material (not shown) may be between/proximate digitline DL and second source/drain region 26. Digitlines DL of different immediately-horizontally-adjacent memory cells MC running into and out of the plane of the page upon which FIG. 3 lies (in the x-direction) may be isolated/spaced relative one another by insulative material 62 (e.g., silicon dioxide and/or silicon nitride). Individual second source/drain regions 26 of individual transistors T that are in different memory-cell tiers 22 are electrically coupled (e.g., directly electrically coupled) to individual digitlines DL. Capacitor C and horizontal transistor T may be considered as being horizontally spaced relative one another along horizontal axis 35 (FIG. 8) along the y-direction.

Capacitor C comprises a storage-node electrode 33, a common electrode 34 (e.g., comprising conductive metal material 70 and conductively-doped polysilicon 71) that is common (directly electrically coupled) to a plurality of capacitors C (at least some, not necessarily all) of memory cells MC, and a capacitor insulator 36 there-between (e.g., dielectric or ferroelectric). Storage-node electrode 33 is directly coupled to first source/drain region 23 of transistor T. Conductively-doped semiconductive material (e.g., conductively-doped epitaxial silicon and not shown) may be between storage-node electrode 33 and first source/drain region 23 (e.g., and such may be considered as a part of either or both). Storage-node electrode 33 for clarity and due to scale is shown as a single material in FIG. 3. However, such comprises multiple materials and structures as is described below.

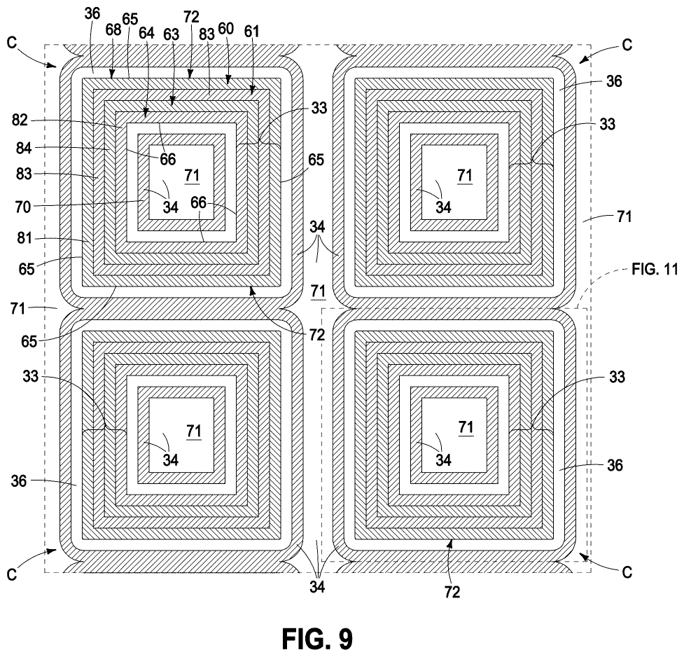

Storage-node electrode 33 comprises a sideways container-like shape 68 that faces horizontally away from horizontal transistor T in a first vertical cross-section that is through and horizontally-elongated along axis 35 (e.g., that of FIG. 8). In a second vertical cross-section that is through and orthogonal to the axis (e.g., that of FIG. 9), storage-node electrode 33 in one embodiment comprises:
a first annular portion 60 comprising titanium oxide 81 (that may or may not be stoichiometric and in some embodiments is alternately referred to as a first conductive material 81);
a second annular portion 61 comprising titanium nitride 83 (that may or may not be stoichiometric and in some embodiments is alternately referred to as a third conductive material 83) radially inward of first annular portion 60;
a third annular portion 63 comprising TiOₓSi_{y}N_{z} 84 radially inward of second annular portion 61, where the x is 1.5 to 2.2, the y is 0.05 to 0.3, and the z is 0.05 to 0.3 (in some embodiments, the material of third annular portion 63 alternately may be considered as being a fourth conductive material 84); and
a fourth annular portion 64 comprising the TiOₓSi_{y}N_{z} 82 radially inward of third annular portion 63, with the x being greater in fourth annular portion 64 than in third annular portion 63 (in some embodiments, the material of fourth annular portion 64 alternately being referred to as a second conductive material 82).

The first, second, third, and fourth annular portions are each intrinsically electrically conductive. Annular portions 60, 61, 63, 64 are shown as being of equal thickness relative one another for ease of depiction but need not be so. In one embodiment, storage-node electrode 33 comprises a radially-outermost conductive surface 65, with first annular portion 60 comprising radially-outermost conductive surface 65. In one embodiment, storage-node electrode 33 comprises a radially-innermost conductive surface 66, with fourth annular portion 64 comprising radially-innermost conductive surface 66. In one embodiment, container-like shape 68 in the first vertical cross-section comprises vertically opposing horizontal walls 72 and a base 73 vertically between walls 72, with such base 73 comprising an outermost surface 74 comprising titanium nitride. In one embodiment, base 73 comprises the same materials as second, third, and fourth annular portions 61, 63, and 64, respectively. Titanium oxide 81 and/or TiOₓSi_{y}N_{z} 82 may also be over the y-direction-ends of titanium nitride 83 and/or TiOₓSi_{y}N_{z} 84 (not shown).

Either or both of third annular portion 63 and fourth annular portion 64 may independently be of uniform composition throughout or be of different compositions throughout relative to the x, y, and/or z (subscripts). In one embodiment, at least the x (subscript) varies in at least one of the third and fourth annular portions 63, 64, respectively. In one embodiment, the x (subscript) increases in fourth annular portion 64 moving radially outward from axis 35. In one embodiment, the x (subscript) is constant in third annular portion 63 and in another embodiment is constant.

Any other attribute(s) or aspect(s) as shown and/or described herein with respect to other embodiments may be used with respect to the above-described embodiments.

In one embodiment, memory circuitry (e.g., that of or comprising construction 8) comprises vertically-stacked memory cells (e.g., MC) individually comprising a horizontal transistor (e.g., T) and a capacitor (e.g., C) electrically coupled therewith. The capacitor and horizontal transistor are horizontally spaced relative one another along an axis 35. The capacitor comprises a storage-node electrode (e.g., 33), a common electrode (e.g., 34) that is common to a plurality of the capacitors of the memory cells, and a capacitor insulator (e.g., 36) between the storage-node and common electrodes. The storage-node electrode comprises a sideways container-like shape (e.g., 68 that faces horizontally away from the horizontal transistor in a first vertical cross-section that is through and horizontally-elongated along the axis (e.g., that of FIG. 8). In a second vertical cross-section that is through and orthogonal to the axis (e.g., that of FIG. 9), the storage-node electrode comprises:
a radially-outermost conductive surface 65 comprising a first conductive material 81 (regardless of whether being titanium oxide); and
a radially-innermost conductive surface 66 comprising a second conductive material 82 (regardless of whether being TiOₓSi_{y}N_{z}) that is of different composition from that of first conductive material 81.

In one embodiment, container-like shape 68 in the first vertical cross-section comprises vertically opposing horizontal walls 72 and a base 73 vertically between walls 72, with base 73 in the first vertical cross-section comprising an outermost surface 74 relative container-like shape 68 that comprises a third conductive material 83 (regardless of whether being titanium nitride) comprising a composition that is different from those of each of first and second conductive materials 81, 82, respectively.

In one embodiment, storage-node electrode 33 comprises a first annular portion 60 comprising radially-outermost conductive surface 65, a second annular portion 61 radially inward of first annular portion 60, a third annular portion 63 radially inward of second annular portion 61, and a fourth annular portion 64 radially inward of third annular portion 63 and comprising radially-innermost conductive surface 66. Second and third annular portions 61 and 63, respectively, are of different compositions relative one another and relative the first and second conductive materials 81 and 82, respectively.

Any other attribute(s) or aspect(s) as shown and/or described herein with respect to other embodiments may be used.

In one embodiment, a capacitor (e.g., C, and regardless of whether one of a plurality of capacitors) comprises a first capacitor electrode (e.g., 33), a second capacitor electrode (e.g., 34 and regardless of whether there are, and common to, a plurality of capacitors), and a capacitor insulator (e.g., 36) between the first and second capacitor electrodes. The storage-node electrode comprises a container-like shape (e.g., 68 and regardless of whether horizontal or sideways) comprising an axis (e.g., 35 and regardless of x, y, z [directions] orientation of the axis). In a cross-section that is through and elongated along the axis (e.g., that of FIG. 8), the storage-node electrode comprises:
a radially-outermost conductive surface 65 comprising a first conductive material 81; and
a radially-innermost conductive surface 66 comprising a second conductive material 82 that is of different composition from that of first conductive material 81.
   Any Other Attribute(s) or Aspect(s) As Shown And/or Described Herein With Respect to other embodiments may be used.

Embodiments of the invention encompass methods used in forming memory circuitry, by way of example only that incorporates device/structure as referred to above. Nevertheless, the method embodiments may incorporate, form, and/or have any of the attributes described with respect to device embodiments.

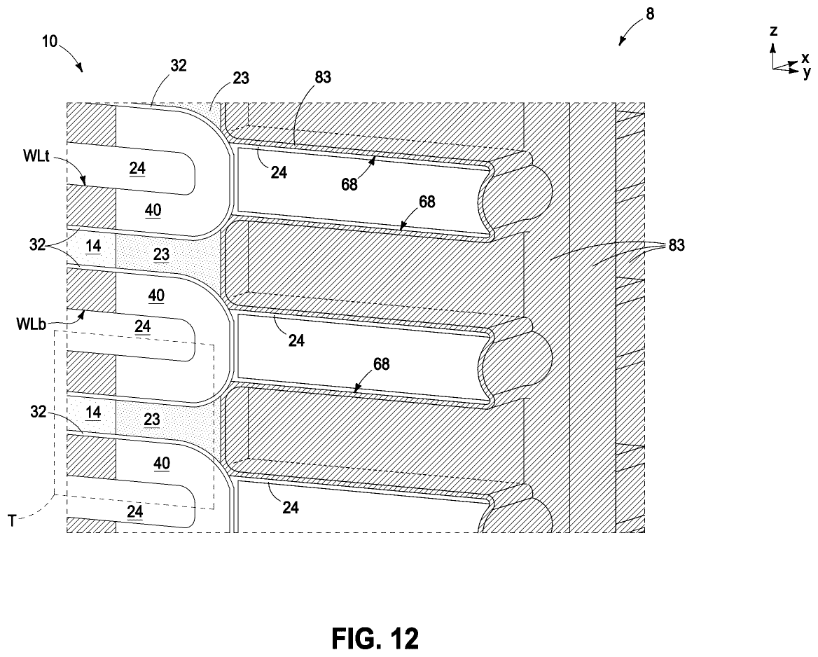

First example method embodiments are described with reference to FIGS. 12-18 which, by way of example, sequentially show predecessor constructions in such example methods used in forming memory circuitry in accordance with some embodiments of the invention. Such memory circuitry ultimately comprises vertically-stacked memory cells individually comprising a horizontal transistor and a capacitor electrically coupled (e.g., directly) therewith. Such memory circuitry may comprise structural embodiments of the invention as described above with respect to FIGS. 3-11. Regardless, the capacitor and horizontal transistor will be horizontally spaced relative one another along an axis (e.g., 35 in FIG. 8). The capacitor will comprise a storage-node electrode (e.g., 33 in FIG. 8), a common electrode (e.g., 34 in FIG. 8) that is common to a plurality of the capacitors of the memory cells, and a capacitor insulator (e.g., 36 in FIG. 8) between the storage-node and common electrodes.

Referring to FIG. 12, titanium nitride 83 (e.g., 45 to 250 Angstroms) of storage-node electrode 33 (in FIG. 8) has been formed to comprise a sideways container-like shape 68 that faces horizontally away from horizontal transistor T in a first vertical cross-section that is through and horizontally-elongated along axis 35 (e.g., along direction y and that of FIG. 8).

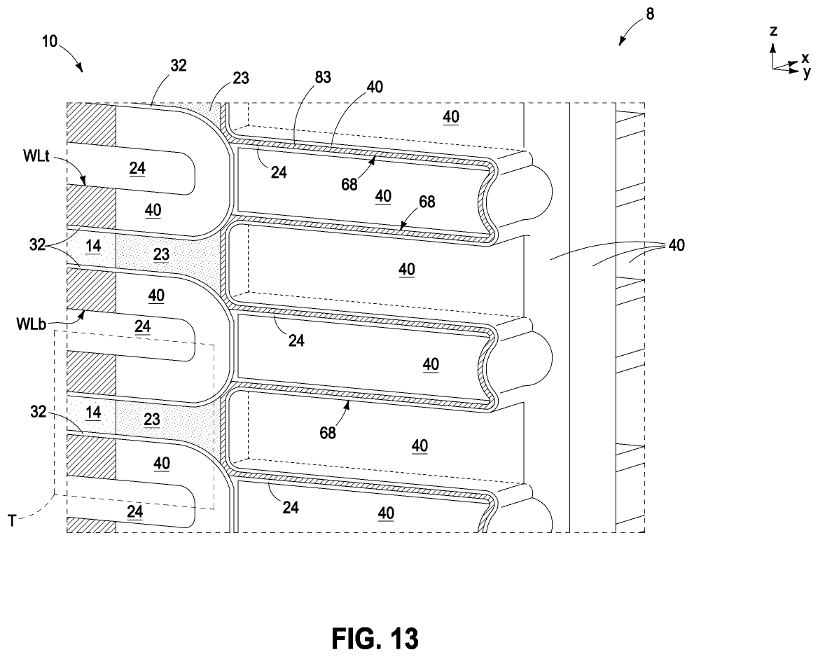

Referring to FIG. 13, silicon nitride 40 (e.g., 5 to 20 Angstroms) has been formed directly against titanium nitride 83 in sideways container-like shape 68.

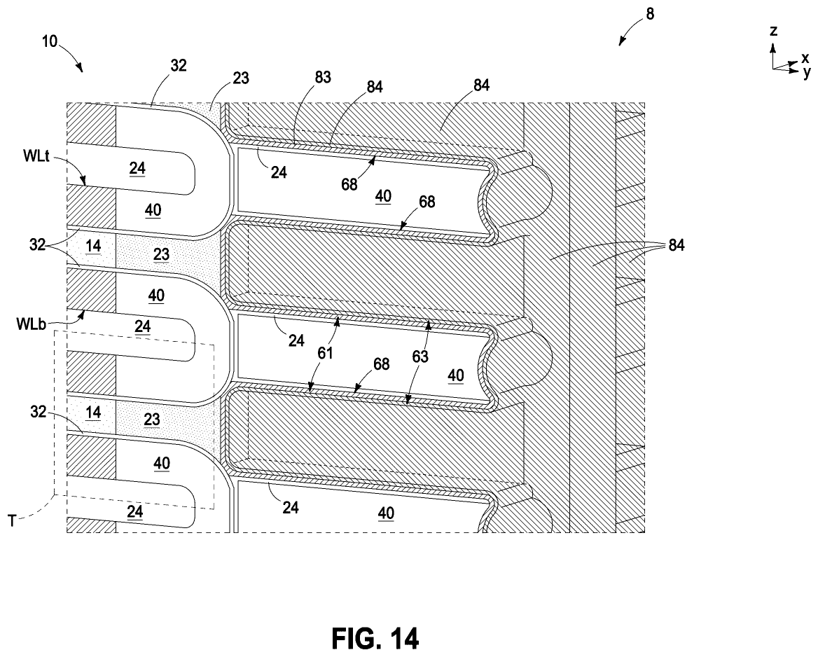

Referring to FIG. 14, an annealing has occurred (e.g., a first annealing) of silicon nitride 40 (no longer shown) and titanium nitride 83 in the presence of oxygen (e.g., O₂ and/or O₃) to form sideways container-like shape 68 of the storage-node electrode to comprise, in a second vertical cross-section that is through and orthogonal to axis 35 (e.g., that of FIG. 9):
a second annular portion 61 comprising titanium nitride 83 (e.g., 5 to 300 Angstroms) (e.g., a first annular portion being formed subsequently as described below); and
a third annular portion 63 comprising TiOₓSi_{y}N_{z} 84 (e.g., 5 to 20 Angstroms) radially inward of second annular portion 61, where the x is 0.05 to 0.3, the y is 0.05 to 0.3, and the z is 0.05 to 0.3.
   Titanium nitride 83 and/or silicon nitride 40 might originally be slightly thicker/thinner and relative one another than is shown, with such annealing consuming some of titanium nitride 83 and with thickness of TiOₓSi_{y}N_{z} 84 perhaps being thicker than original silicon nitride 40 due to oxygen being added from the annealing. Any suitable annealing conditions (with or without plasma, whether direct or remote) in the presence of an oxygen-containing precursor may be used, with 100° C. to 500° C., 10 mTorr to 760 Torr, and for 15 seconds to 2 hours being an example. Lower temperatures may be preferred (e.g., using O₃ at below 300° C. for 30 minutes) for more controlled and/or uniform oxidation, reduced thermal stress, reduced mechanical stress, and less risk of deformation.

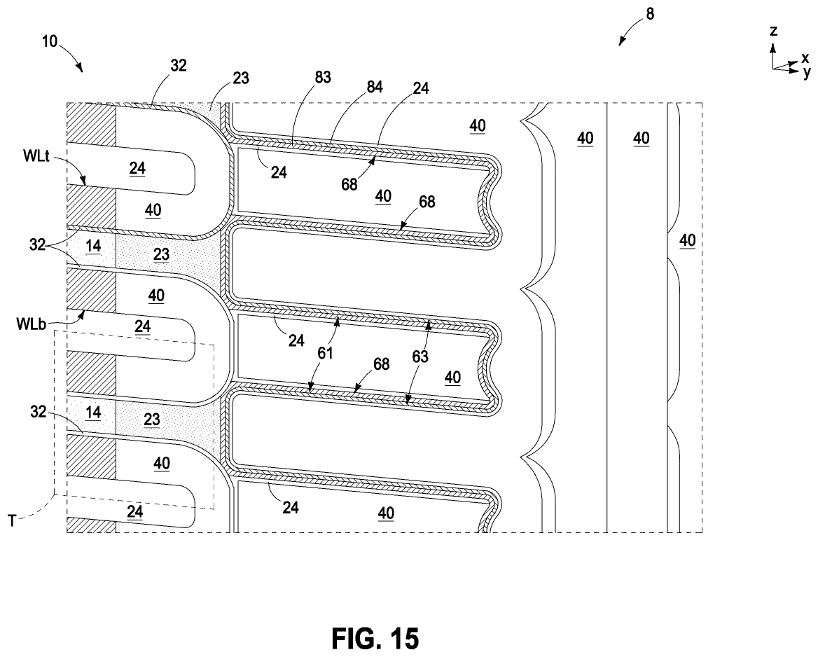

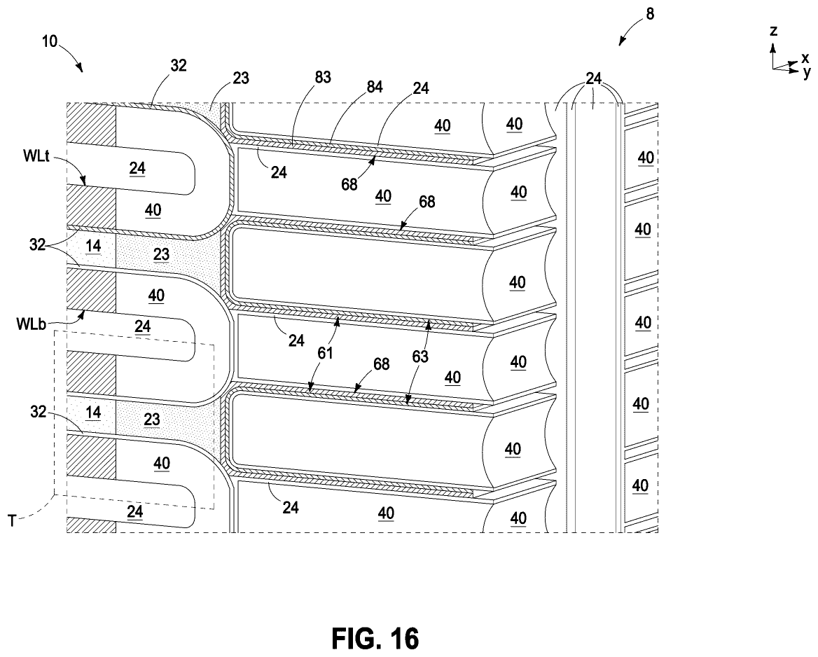

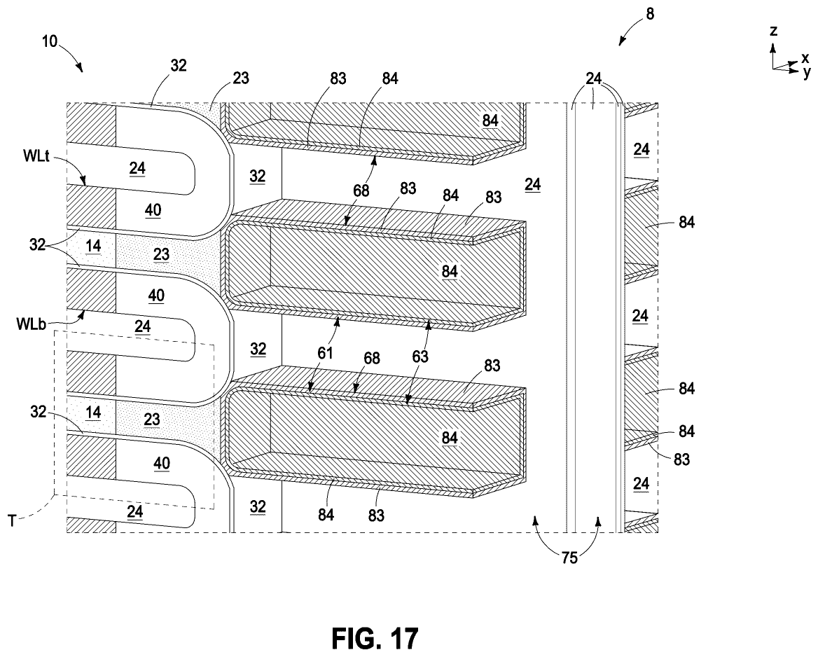

Referring to FIG. 15, and in one embodiment, silicon dioxide 24 and silicon nitride 40 have been formed. FIG. 16 shows materials 24, 40, 83, and 84 having been etched back to isolate such from being interconnected between the immediately-z-direction-adjacent memory-cell tiers. FIG. 17 shows etching of silicon dioxide 24 and silicon nitride 40 from being internally within and externally above and below sideways container-like shape 68 and to expose titanium nitride 83 and TiOₓSi_{y}N_{z} 84. A wall 75 comprising insulative material 24 (and over which titanium nitride 83 was formed in FIG. 12) is visible laterally between the example two adjacent vertical columns of sideways container-like shapes 68.

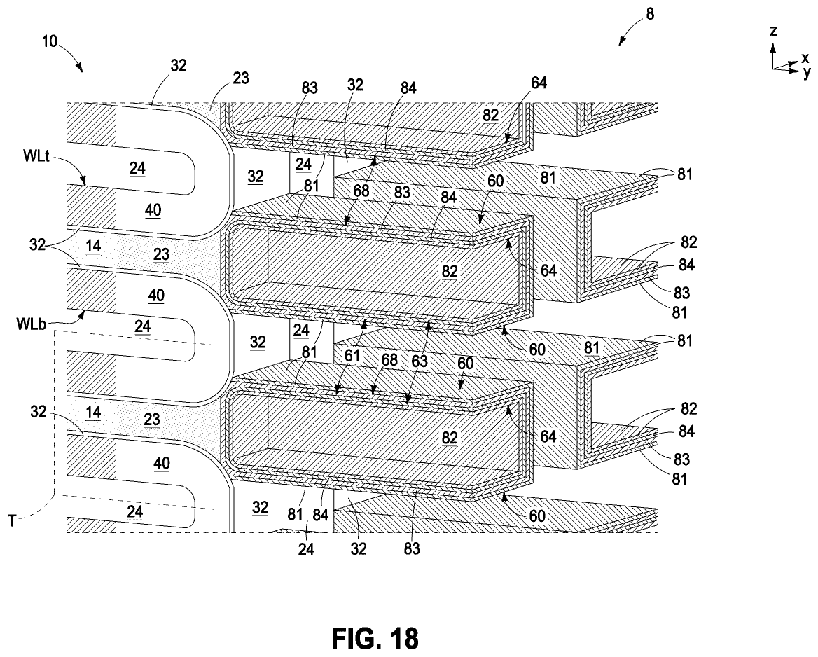

Referring to FIG. 18, example wall 75 has been removed and another annealing has occurred (e.g., a second annealing temporally relative to the first annealing, and regardless of whether there is any other annealing between the first and the second), this time of second and third annular portions 61 and 63, respectively, in the presence of oxygen (e.g., O₂ and/or O₃) to form: a first annular portion 60 comprising titanium oxide 81 (e.g., 5 to 20 Angstroms) radially outward of second annular portion 61; and
a fourth annular portion 64 comprising the TiOₓSi_{y}N_{z} 82 (e.g., 5 to 20 Angstroms) radially inward of third annular portion 63, with the x being greater in fourth annular portion 64 than in third annular portion 63.
   Wall 75 may be removed earlier, later, or not be formed. Annealing conditions may be as described above. Titanium nitride 83 and/or TiOₓSi_{y}N_{z} 84 might originally be slightly thicker/thinner and relative one another than is shown, with such annealing consuming some of titanium nitride 83 to form titanium oxide 81 (nitrogen going off as a gas) and with resultant TiOₓSi_{y}N_{z} 84 being thinner or thicker than originally due to the annealing. Titanium oxide 81 and TiOₓSi_{y}N_{z} 82 would also likely form over the y-direction-ends of titanium nitride 83 and TiOₓSi_{y}N_{z} 84 (not shown).

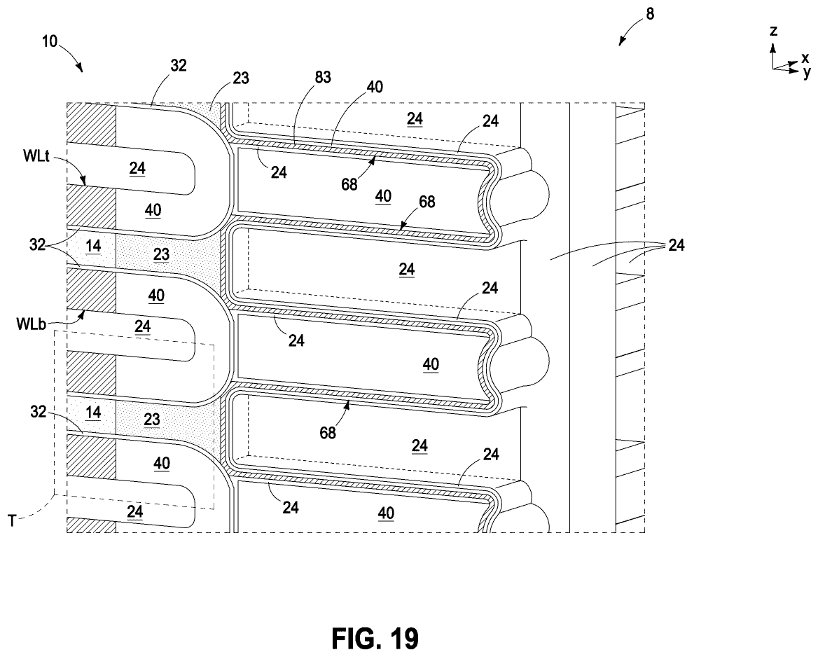

In one embodiment, silicon dioxide 24 is formed directly against silicon nitride 40 in sideways container-like shape 68 before the first annealing, for example as shown in FIG. 19 as an optional additional step between those shown by FIGS. 13 and 14.

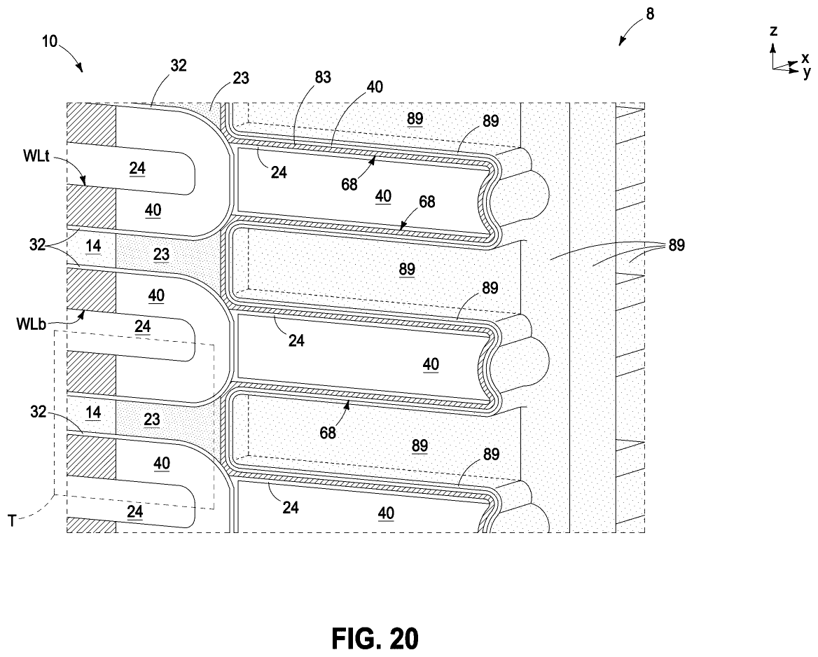

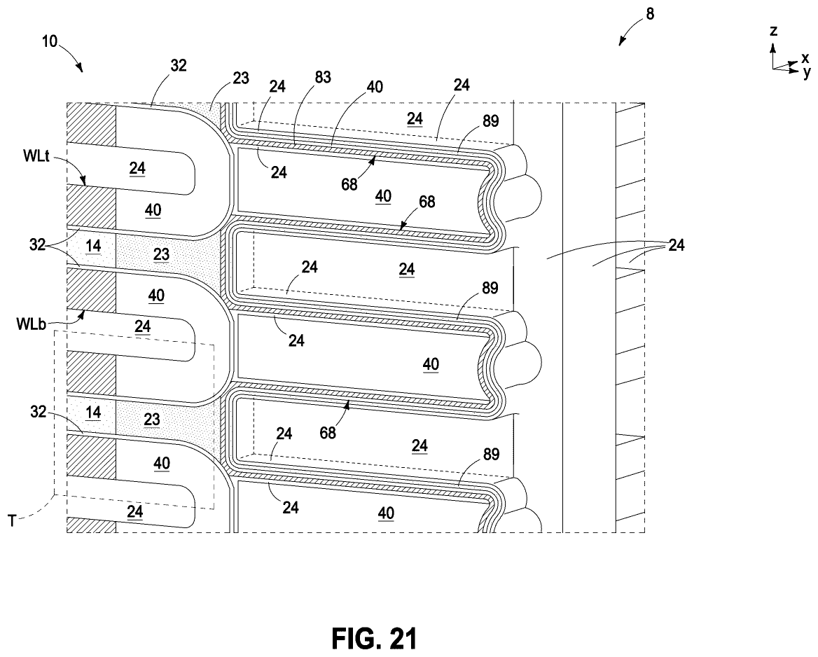

In one embodiment, silicon 89 is formed directly against silicon nitride 40 in sideways container-like shape 68 before the first annealing, for example as shown in FIG. 20 as an optional additional step between those shown by FIGS. 13 and 14. In one such latter embodiment, silicon dioxide 24 may be formed directly against silicon 89 in sideways container-like shape 68 before the first annealing (e.g., as shown in FIG. 21).

In another embodiment, and referring to FIG. 19, silicon nitride 40 is formed directly against titanium nitride 83 and silicon dioxide 24 is formed directly against silicon nitride 40. Then, FIG. 14 can be considered as showing inherent subsequent processing directly from FIG. 19 in the absence of a dedicated first annealing and that inherently forms sideways container-like shape 68 of the storage-node electrode to comprise, in a second vertical cross-section that is through and orthogonal to the axis (e.g., that of FIG. 9):
a second annular portion 61 comprising titanium nitride 83; and

a third annular portion 63 comprising TiOₓSi_{y}N_{z} 84 radially inward of the second annular portion, where the x is 1.5 to 2.2, the y is 0.05 to 0.3, and the z is 0.05 to 0.3.
annealing conditions may be as described above.

Thereafter, and referring to FIG. 18 (processing as shown in FIGS. 15-17 may having been conducted before that shown by FIG. 18), second and third annular portions 61 and 63, respectively, are annealed in the presence of oxygen (e.g., O₂ and/or O₃) to form:
a first annular portion 60 comprising titanium oxide 81 radially outward of second annular portion 61; and
a fourth annular portion 64 comprising the TiOₓSi_{y}N_{z} 82 radially inward of third annular portion 63, with the x being greater in fourth annular portion 64 than in third annular portion 64.

Annealing conditions may be as described above. As stated above, titanium oxide 81 and TiOₓSi_{y}N_{z} 82 would also likely form over the y-direction-ends of titanium nitride 83 and TiOₓSi_{y}N_{z} 84 (not shown).

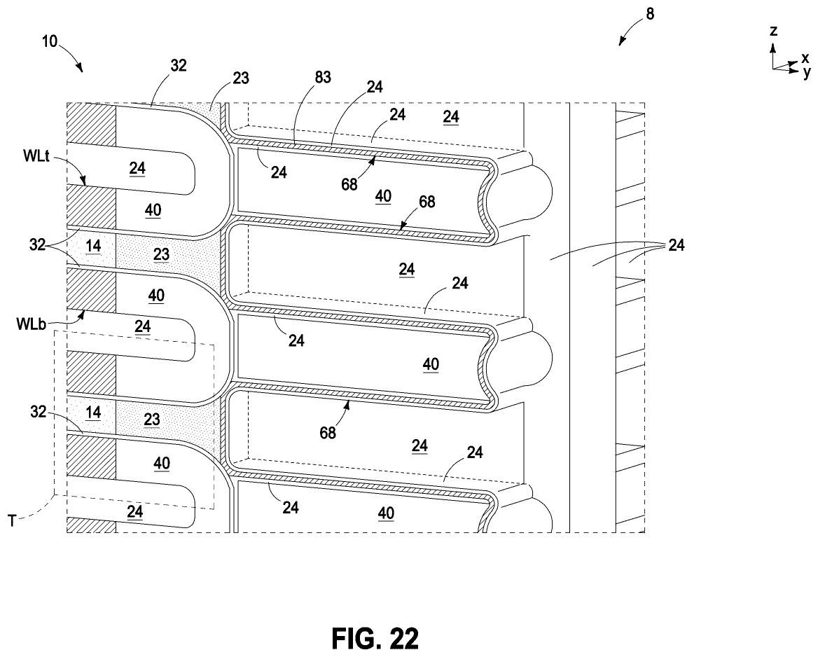

In another embodiment, and referring to FIG. 22, silicon dioxide 24 is formed directly against titanium nitride 83 in sideways container-like shape 68.

Then, FIG. 14 can be considered as showing first annealing of silicon dioxide 24 (no longer shown) and titanium nitride 83 (regardless of whether in the presence of oxygen) directly from FIG. 22 to form sideways container-like shape 68 of storage-node electrode 33 to comprise, in a second vertical cross-section that is through and orthogonal to the axis:
a second annular portion 61 comprising titanium nitride 83; and
a third annular portion 63 comprising TiOₓSi_{y}N_{z} 84 radially inward of the second annular portion, where the x is 1.5 to 2.2, the y is 0.05 to 0.3, and the z is 0.05 to 0.3.

Thereafter, and referring to FIG. 18 (processing as shown in FIGS. 15-17 may having been conducted before that shown by FIG. 18), a second annealing has occurred, this time of second and third annular portions 61 and 63, respectively, in the presence of oxygen (e.g., O₂ and/or O₃) to form:
a first annular portion 60 comprising titanium oxide 81 radially outward of second annular portion 61; and
a fourth annular portion 64 comprising the TiOₓSi_{y}N_{z} 82 radially inward of third annular portion 63, with the x being greater in fourth annular portion 64 than in third annular portion 63.
   annealing conditions may be as described above.

In one such embodiment, the first annealing inherently occurs during the forming of the silicon dioxide to form at least of a majority (greater than 50% up to and including 100%) of the second and third annular portions during the forming of the silicon dioxide. In another such embodiment, the first annealing occurs after the forming of the silicon dioxide such that at least of a majority of the second and third annular portions are formed after the forming of the silicon dioxide.

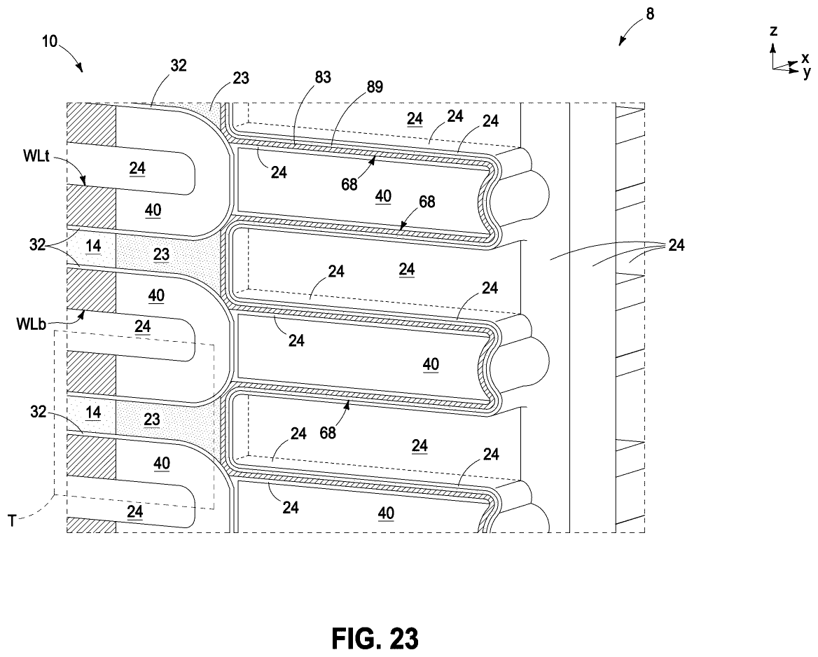

In another embodiment, and referring to FIG. 23, silicon 89 is formed directly against titanium nitride 83 in sideways container-like shape 68, followed by forming silicon dioxide 24 directly against silicon 89 in sideways container-like shape 68. Then, FIG. 14 can be considered as showing inherent subsequent processing directly from FIG. 23 in the absence of a dedicated first annealing and that inherently forms sideways container-like shape 68 of storage-node electrode 33 to comprise, in a second vertical cross-section that is through and orthogonal to axis 35 (e.g., that of FIG. 9):
a second annular portion 61 comprising titanium nitride 83; and
a third annular portion 63 comprising TiOₓSi_{y}N_{z} 84 radially inward of the second annular portion, where the x is 1.5 to 2.2, the y is 0.05 to 0.3, and the z is 0.05 to 0.3.
   Annealing conditions may be as described above.

Thereafter, and referring to FIG. 18 (processing as shown in FIGS. 15-17 may having been conducted before that shown by FIG. 18), second and third annular portions 61 and 63, respectively, are annealed in the presence of oxygen (e.g., O₂ and/or O₃) to form:
a first annular portion 60 comprising titanium oxide 81 radially outward of second annular portion 61; and
a fourth annular portion 64 comprising the TiOₓSi_{y}N_{z} 82 radially inward of third annular portion 63, with the x being greater in fourth annular portion 64 than in third annular portion 64.
   Annealing conditions may be as described above.

Alternately in such another embodiment, annealing may be conducted of the titanium nitride and the silicon to form the second and third annular portions before the annealing of the second and third annular portions that forms the first and fourth annular portions. Annealing conditions may be as described above.

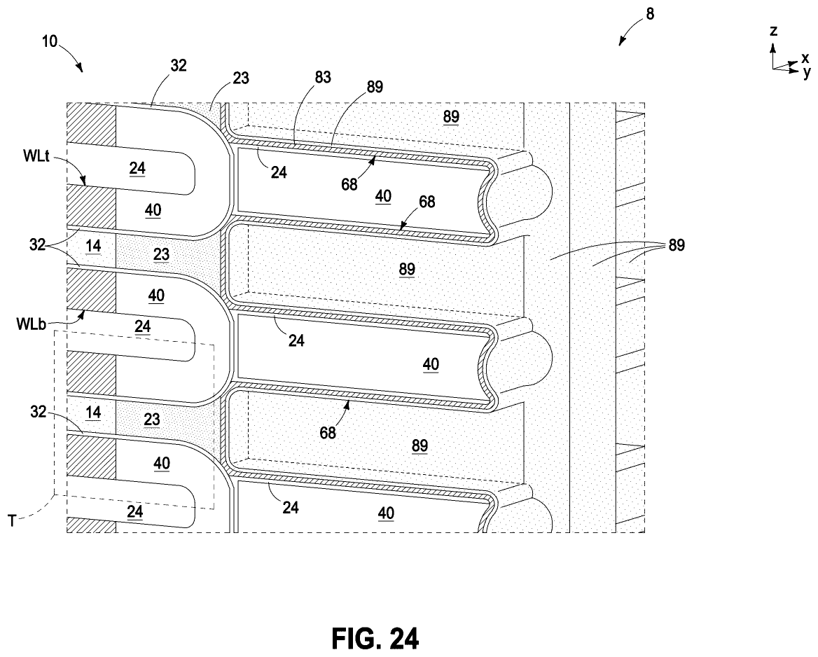

In another embodiment, and referring to FIG. 24, silicon 89 has been formed directly against titanium nitride 83 in sideways container-like shape 68.

Then, FIG. 14 can be considered as showing first annealing of silicon 89 (no longer shown) and titanium nitride 83 in the presence of oxygen (e.g., O₂ and/or O₃) directly from FIG. 24 to form sideways container-like shape 68 of storage-node electrode 33 to comprise, in a second vertical cross-section that is through and orthogonal to axis 35 (e.g., that of FIG. 9):
a second annular portion 61 comprising titanium nitride 83; and
a third annular portion 63 comprising TiOₓSi_{y}N_{z} 84 radially inward of the second annular portion, where the x is 1.5 to 2.2, the y is 0.05 to 0.3, and the z is 0.05 to 0.3.
   Annealing conditions may be as described above.

Thereafter, and referring to FIG. 18 (processing as shown in FIGS. 15-17 may having been conducted before that shown by FIG. 18), a second annealing has been conducted of second and third annular portions 61 and 63, respectively, in the presence of oxygen (e.g., O₂ and/or O₃) to form:
a first annular portion 60 comprising titanium oxide 81 radially outward of second annular portion 61; and
a fourth annular portion 64 comprising the TiOₓSi_{y}N_{z} 82 radially inward of third annular portion 63, with the x being greater in fourth annular portion 64 than in third annular portion 63.
   Annealing conditions may be as described above.

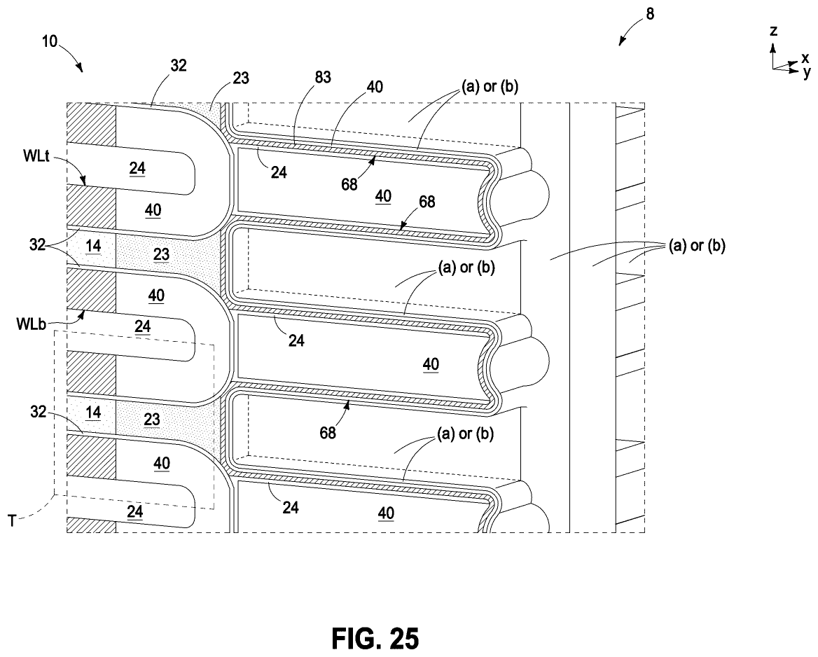

In another embodiment, and referring to FIG. 25, silicon nitride 40 has been formed directly against titanium nitride 83 in sideways container-like shape 68. One of (a) or (b) has been formed directly against silicon nitride 40 in sideways container-like shape 68, with the (a) being silicon and the (b) being silicon dioxide. Then, FIG. 14 can be considered as showing inherent subsequent processing directly from FIG. 25 in the absence of a dedicated first annealing and that inherently forms sideways container-like shape 68 of storage-node electrode 33 to comprise, in a second vertical cross-section that is through and orthogonal to axis 35 (e.g., that of FIG. 9):
a second annular portion 61 comprising titanium nitride 83; and
a third annular portion 63 comprising TiOₓSi_{y}N_{z} 84 radially inward of the second annular portion, where the x is 1.5 to 2.2, the y is 0.05 to 0.3, and the z is 0.05 to 0.3.
   Annealing conditions may be as described above.

Thereafter, and referring to FIG. 18 (processing as shown in FIGS. 15-17 may having been conducted before that shown by FIG. 18), a second annealing has been conducted of second and third annular portions 61 and 63, respectively, in the presence of oxygen (e.g., O₂ and/or O₃) to form:
a first annular portion 60 comprising titanium oxide 81 radially outward of second annular portion 61; and
a fourth annular portion 64 comprising the TiOₓSi_{y}N_{z} 82 radially inward of third annular portion 63, with the x being greater in fourth annular portion 64 than in third annular portion 63.
   Annealing conditions may be as described above.

In one such embodiment, the (a) or the (b) comprises the (b). In an alternate such embodiment, the (a) or the (b) comprises the (a). In one such latter embodiment, silicon dioxide is formed on the (a) before forming at least a majority of the second and third annular portions.

Regardless of which of the above example method embodiments might be used, a capacitor insulator (e.g., 36) and a common electrode (e.g., 34) may be subsequently formed, for example to produce a construction as shown by FIGS. 3-11.

Capacitors having storage-node electrodes comprising a container-like shape with different composition radially-innermost and radially-outermost surfaces, and memory circuitry as described herein incorporating such capacitors, may improve or maximize static capacitance and/or reliability while maintaining acceptable leakage or even reducing leakage. Alternately, such capacitors may reduce leakage regardless of any improvement in static capacitance.

The various alternate or different embodiment methods described above may be used to optimize or trade-off with respect to various aspects of a resultant construction, for example control of x, y, and/or z (subscripts), mechanical robustness, conductivity, work function, and/or thermal stability of the container-shaped storage-node electrode of the capacitor(s).

The above processing(s) or construction(s) may be considered as being relative to an array of components formed as or within a single stack or single deck of such components above or as part of an underlying base substrate (albeit, the single stack/deck may have multiple tiers). Control and/or other peripheral circuitry for operating or accessing such components within an array may also be formed anywhere as part of the finished construction, and in some embodiments may be under the array (e.g., CMOS under-array). Regardless, one or more additional such stack(s)/deck(s) may be provided or fabricated above and/or below that shown in the figures or described above. Further, the array(s) of components may be the same or different relative one another in different stacks/decks and different stacks/decks may be of the same thickness or of different thicknesses relative one another. Intervening structure may be provided between immediately-vertically-adjacent stacks/decks (e.g., additional circuitry and/or dielectric layers). Also, different stacks/decks may be electrically coupled relative one another. The multiple stacks/decks may be fabricated separately and sequentially (e.g., one atop another), or two or more stacks/decks may be fabricated at essentially the same time.

The circuitry described herein (e.g., conductive vias thereof) may connect with circuitry that is on either the top or the bottom (i.e., either z-axis side) of a vertical stack regardless of orientation of the construction in three-dimensional space and which is not material to aspects of the inventions disclosed herein. For example, and by way of example only, conductive vias may connect with peripheral control circuitry that is beneath the stack with respect to the orientation shown in the drawings. As an alternate example, and by way of example only, conductive vias may connect with peripheral control circuitry that is above the stack with respect to the shown orientation, for example to another substrate having such circuitry and that is bonded with the top of the stack with respect to the shown orientation. In such alternate example, the construction may be inverted from the shown orientation and then bonded with the other substrate. Further, in such alternate example, electronic components may be fabricated relative to the bottom of the stack with respect to the shown orientation but inverted therefrom during processing. Such electronic components may connect with conductive vias that extend through the stack to the substrate bonded with the other side that has such peripheral control circuitry. Regardless, constructions as shown and described herein may be processed, packaged, and/or mounted in any three-dimensional spatial orientation.

The assemblies and structures discussed above may be used in integrated circuits/circuitry and may be incorporated into electronic systems. Such electronic systems may be used in, for example, memory modules, device drivers, power modules, communication modems, processor modules, and application-specific modules, and may include multilayer, multichip modules. The electronic systems may be any of a broad range of systems, such as, for example, cameras, wireless devices, displays, chip sets, set top boxes, games, lighting, vehicles, clocks, televisions, cell phones, personal computers, automobiles, industrial control systems, aircraft, etc.

In this document unless otherwise indicated, “elevational”, “higher”, “upper”, “lower”, “top”, “atop”, “bottom”, “above”, “below”, “under”, “beneath”, “up”, and “down” are generally with reference to the vertical direction. “Horizontal” refers to a general direction (i.e., within 10 degrees) along a primary substrate surface and may be relative to which the substrate is processed during fabrication, and vertical is a direction generally orthogonal thereto. Reference to “exactly horizontal” is the direction along the primary substrate surface (i.e., no degrees there-from) and may be relative to which the substrate is processed during fabrication and as shown in drawings (if any) herein. Further, “vertical” and “horizontal” as used herein are generally perpendicular directions relative one another and independent of orientation of the substrate in three-dimensional space during fabrication and/or in a finished construction. Additionally, “elevationally-extending” and “extend(ing) elevationally” refer to a direction that is angled away by at least 45° from exactly horizontal. Further, “extend(ing) elevationally”, “elevationally-extending”, “extend(ing) horizontally”, “horizontally-extending” and the like with respect to a field effect transistor are with reference to orientation of the transistor's channel length along which current flows in operation between the source/drain regions. For bipolar junction transistors, “extend(ing) elevationally” “elevationally-extending”, “extend(ing) horizontally”, “horizontally-extending” and the like, are with reference to orientation of the base length along which current flows in operation between the emitter and collector. In some embodiments, any component, feature, and/or region that extends elevationally extends vertically or within 10°of vertical.

Further, “directly above”, “directly below”, and “directly under” require at least some lateral overlap (i.e., horizontally) of two stated regions/materials/components relative one another. Also, use of “above” not preceded by “directly” only requires that some portion of the stated region/material/component that is above the other be elevationally outward of the other (i.e., independent of whether there is any lateral overlap of the two stated regions/materials/components). Analogously, use of “below” and “under” not preceded by “directly” only requires that some portion of the stated region/material/component that is below/under the other be elevationally inward of the other (i.e., independent of whether there is any lateral overlap of the two stated regions/materials/components).

Any of the materials, regions, and structures described herein may be homogenous or non-homogenous, and regardless may be continuous or discontinuous over any material which such overlie. Where one or more example composition(s) is/are provided for any material, that material may comprise, consist essentially of, or consist of such one or more composition(s). Further, unless otherwise stated, each material may be formed using any suitable existing or future-developed technique, with atomic layer deposition, chemical vapor deposition, physical vapor deposition, epitaxial growth, diffusion doping, and ion implanting being examples.

Additionally, “thickness” by itself (no preceding directional adjective) is defined as the mean straight-line distance through a given material or region perpendicularly from a closest surface of an immediately-adjacent material of different composition or of an immediately-adjacent region. Additionally, the various materials or regions described herein may be of substantially constant thickness or of variable thickness. If of variable thickness, thickness refers to average thickness unless otherwise indicated, and such material or region will have some minimum thickness and some maximum thickness due to the thickness being variable. As used herein, “different composition” only requires those portions of two stated materials or regions that may be directly against one another to be chemically and/or physically different, for example if such materials or regions are not homogenous. If the two stated materials or regions are not directly against one another, “different composition” only requires that those portions of the two stated materials or regions that are closest to one another be chemically and/or physically different if such materials or regions are not homogenous. In this document, a material, region, or structure is “directly against” another when there is at least some physical touching contact of the stated materials, regions, or structures relative one another. In contrast, “over”, “on”, “adjacent”, “along”, and “against” not preceded by “directly” encompass “directly against” as well as construction where intervening material(s), region(s), or structure(s) result(s) in no physical touching contact of the stated materials, regions, or structures relative one another.

Herein, regions-materials-components are “electrically coupled” relative one another if in normal operation electric current is capable of continuously flowing from one to the other and does so predominately by movement of subatomic positive and/or negative charges when such are sufficiently generated. Another electronic component may be between and electrically coupled to the regions-materials-components. In contrast, when regions-materials-components are referred to as being “directly electrically coupled”, no intervening electronic component (e.g., no diode, transistor, resistor, transducer, switch, fuse, etc.) is between the directly electrically coupled regions-materials-components.

Any use of “row” and “column” in this document is for convenience in distinguishing one series or orientation of features from another series or orientation of features and along which components have been or may be formed. “Row” and “column” are used synonymously with respect to any series of regions, components, and/or features independent of function. Regardless, the rows may be straight and/or curved and/or parallel and/or not parallel relative one another, as may be the columns. Further, the rows and columns may intersect relative one another at 90°or at one or more other angles (i.e., other than the straight angle).

The composition of any of the conductive/conductor/conducting materials herein may be conductive metal material and/or conductively-doped semiconductive/semiconductor/semiconducting material. “Metal material” is any one or combination of an elemental metal, any mixture or alloy of two or more elemental metals, and any one or more metallic compound(s).

Herein, any use of “selective” as to etch, etching, removing, removal, depositing, forming, and/or formation is such an act of one stated material relative to another stated material(s) so acted upon at a rate of at least 2:1 by volume. Further, any use of selectively depositing, selectively growing, or selectively forming is depositing, growing, or forming one material relative to another stated material or materials at a rate of at least 2:1 by volume for at least the first 75 Angstroms of depositing, growing, or forming.

Unless otherwise indicated, use of “or” herein encompasses either and both.

### Conclusion

In some embodiments, a method is used in forming memory circuitry. The memory circuitry ultimately comprises vertically-stacked memory cells individually comprising a horizontal transistor and a capacitor electrically coupled therewith. The capacitor and horizontal transistor are horizontally spaced relative one another along an axis. The capacitor comprises a storage-node electrode, a common electrode that is common to a plurality of the capacitors of the memory cells, and a capacitor insulator between the storage-node and common electrodes. The method comprises forming titanium nitride of the storage-node electrode to comprise a sideways container-like shape that faces horizontally away from the horizontal transistor in a first vertical cross-section that is through and horizontally-elongated along the axis. Silicon nitride is formed directly against the titanium nitride in the sideways container-like shape. The silicon nitride and the titanium nitride are first annealed in the presence of oxygen to form the sideways container-like shape of the storage-node electrode to comprise, in a second vertical cross-section that is through and orthogonal to the axis, a second annular portion comprising titanium nitride and a third annular portion comprising TiOₓSi_{y}N_{z} radially inward of the second annular portion, where the x is 1.5 to 2.2, the y is 0.05 to 0.3, and the z is 0.05 to 0.3. The second and third annular portions are second annealed in the presence of oxygen to form a first annular portion comprising titanium oxide radially outward of the second annular portion and a fourth annular portion comprising the TiOₓSi_{y}N_{z} radially inward of the third annular portion, with the x being greater in the fourth annular portion than in the third annular portion.

In some embodiments, a method is used in forming memory circuitry. The memory circuitry ultimately comprises vertically-stacked memory cells individually comprising a horizontal transistor and a capacitor electrically coupled therewith. The capacitor and horizontal transistor are horizontally spaced relative one another along an axis. The capacitor comprises a storage-node electrode, a common electrode that is common to a plurality of the capacitors of the memory cells, and a capacitor insulator between the storage-node and common electrodes. The method comprises forming titanium nitride of the storage-node electrode to comprise a sideways container-like shape that faces horizontally away from the horizontal transistor in a first vertical cross-section that is through and horizontally-elongated along the axis. Silicon nitride is formed directly against the titanium nitride in the sideways container-like shape. Silicon dioxide is formed directly against the silicon nitride in the sideways container-like shape and forms the sideways container-like shape of the storage-node electrode to comprise, in a second vertical cross-section that is through and orthogonal to the axis, a second annular portion comprising titanium nitride, and a third annular portion comprising TiOₓSi_{y}N_{z} radially inward of the second annular portion, where the x is 1.5 to 2.2, the y is 0.05 to 0.3, and the z is 0.05 to 0.3. The second and third annular portions are annealed in the presence of oxygen to form a first annular portion comprising titanium oxide radially outward of the second annular portion and a fourth annular portion comprising the TiOₓSi_{y}N_{z} radially inward of the third annular portion, with the x being greater in the fourth annular portion than in the third annular portion.

In some embodiments, a method is used in forming memory circuitry. The memory circuitry ultimately comprises vertically-stacked memory cells individually comprising a horizontal transistor and a capacitor electrically coupled therewith. The capacitor and horizontal transistor are horizontally spaced relative one another along an axis. The capacitor comprises a storage-node electrode, a common electrode that is common to a plurality of the capacitors of the memory cells, and a capacitor insulator between the storage-node and common electrodes. The method comprises forming titanium nitride of the storage-node electrode to comprise a sideways container-like shape that faces horizontally away from the horizontal transistor in a first vertical cross-section that is through and horizontally-elongated along the axis. Silicon dioxide is formed directly against the titanium nitride in the sideways container-like shape. The silicon dioxide and the titanium nitride are first annealed to form the sideways container-like shape of the storage-node electrode to comprise, in a second vertical cross-section that is through and orthogonal to the axis, a second annular portion comprising titanium nitride, and a third annular portion comprising TiOₓSi_{y}N_{z} radially inward of the second annular portion, where the x is 1.5 to 2.2, the y is 0.05 to 0.3, and the z is 0.05 to 0.3. The second and third annular portions are second annealed in the presence of oxygen to form a first annular portion comprising titanium oxide radially outward of the second annular portion and a fourth annular portion comprising the TiOₓSi_{y}N_{z} radially inward of the third annular portion, with the x being greater in the fourth annular portion than in the third annular portion.

In some embodiments, a method is used in forming memory circuitry. The memory circuitry ultimately comprises vertically-stacked memory cells individually comprising a horizontal transistor and a capacitor electrically coupled therewith. The capacitor and horizontal transistor are horizontally spaced relative one another along an axis. The capacitor comprises a storage-node electrode, a common electrode that is common to a plurality of the capacitors of the memory cells, and a capacitor insulator between the storage-node and common electrodes. The method comprises forming titanium nitride of the storage-node electrode to comprise a sideways container-like shape that faces horizontally away from the horizontal transistor in a first vertical cross-section that is through and horizontally-elongated along the axis. Silicon is formed directly against the titanium nitride in the sideways container-like shape. Silicon dioxide is formed directly against the silicon in the sideways container-like shape and forms the sideways container-like shape of the storage-node electrode to comprise, in a second vertical cross-section that is through and orthogonal to the axis, a second annular portion comprising titanium nitride, and a third annular portion comprising TiOₓSi_{y}N_{z} radially inward of the second annular portion, where the x is 1.5 to 2.2, the y is 0.05 to 0.3, and the z is 0.05 to 0.3. The second and third annular portions are annealed in the presence of oxygen to form a first annular portion comprising titanium oxide radially outward of the second annular portion and a fourth annular portion comprising the TiOₓSi_{y}N_{z} radially inward of the third annular portion, with the x being greater in the fourth annular portion than in the third annular portion.

In some embodiments, a method is used in forming memory circuitry. The memory circuitry ultimately comprises vertically-stacked memory cells individually comprising a horizontal transistor and a capacitor electrically coupled therewith. The capacitor and horizontal transistor are horizontally spaced relative one another along an axis. The capacitor comprises a storage-node electrode, a common electrode that is common to a plurality of the capacitors of the memory cells, and a capacitor insulator between the storage-node and common electrodes. The method comprises forming titanium nitride of the storage-node electrode to comprise a sideways container-like shape that faces horizontally away from the horizontal transistor in a first vertical cross-section that is through and horizontally-elongated along the axis. Silicon nitride is formed directly against the titanium nitride in the sideways container-like shape. One of (a) or (b) are formed directly against the silicon nitride in the sideways container-like shape and forms the sideways container-like shape of the storage-node electrode to comprise, in a second vertical cross-section that is through and orthogonal to the axis, a second annular portion comprising titanium nitride, and a third annular portion comprising TiOₓSi_{y}N_{z} radially inward of the second annular portion, where the x is 1.5 to 2.2, the y is 0.05 to 0.3, and the z is 0.05 to 0.3, where the (a) is silicon and the (b) is silicon dioxide. The second and third annular portions are annealed in the presence of oxygen to form a first annular portion comprising titanium oxide radially outward of the second annular portion and a fourth annular portion comprising the TiOₓSi_{y}N_{z} radially inward of the third annular portion, with the x being greater in the fourth annular portion than in the third annular portion.

In some embodiments, a method is used in forming memory circuitry. The memory circuitry ultimately comprises vertically-stacked memory cells individually comprising a horizontal transistor and a capacitor electrically coupled therewith. The capacitor and horizontal transistor are horizontally spaced relative one another along an axis. The capacitor comprises a storage-node electrode, a common electrode that is common to a plurality of the capacitors of the memory cells, and a capacitor insulator between the storage-node and common electrodes. The method comprises forming titanium nitride of the storage-node electrode to comprise a sideways container-like shape that faces horizontally away from the horizontal transistor in a first vertical cross-section that is through and horizontally-elongated along the axis. Silicon is formed directly against the titanium nitride in the sideways container-like shape. The silicon and the titanium nitride are first annealed in the presence of oxygen to form the sideways container-like shape of the storage-node electrode to comprise, in a second vertical cross-section that is through and orthogonal to the axis, a second annular portion comprising titanium nitride, and a third annular portion comprising TiOₓSi_{y}N_{z} radially inward of the second annular portion, where the x is 1.5 to 2.2, the y is 0.05 to 0.3, and the z is 0.05 to 0.3. The second and third annular portions are second annealed in the presence of oxygen to form a first annular portion comprising titanium oxide radially outward of the second annular portion and a fourth annular portion comprising the TiOₓSi_{y}N_{z} radially inward of the third annular portion, with the x being greater in the fourth annular portion than in the third annular portion.

In some embodiments, memory circuitry comprises vertically-stacked memory cells individually comprising a horizontal transistor and a capacitor electrically coupled therewith. The capacitor and horizontal transistor are horizontally spaced relative one another along an axis. The capacitor comprises a storage-node electrode, a common electrode that is common to a plurality of the capacitors of the memory cells, and a capacitor insulator between the storage-node and common electrodes. The storage-node electrode comprises a sideways container-like shape that faces horizontally away from the horizontal transistor in a first vertical cross-section that is through and horizontally-elongated along the axis. In a second vertical cross-section that is through and orthogonal to the axis, the storage-node electrode comprises a radially-outermost conductive surface comprising a first conductive material, and a radially-innermost conductive surface comprising a second conductive material that is of different composition from that of the first conductive material.

In some embodiments, memory circuitry comprises vertically-stacked memory cells individually comprising a horizontal transistor and a capacitor electrically coupled therewith. The capacitor and horizontal transistor are horizontally spaced relative one another along an axis. The capacitor comprises a storage-node electrode, a common electrode that is common to a plurality of the capacitors of the memory cells, and a capacitor insulator between the storage-node and common electrodes. The storage-node electrode comprises a sideways container-like shape that faces horizontally away from the horizontal transistor in a first vertical cross-section that is through and horizontally-elongated along the axis. In a second vertical cross-section that is through and orthogonal to the axis, the storage-node electrode comprises a first annular portion comprising titanium oxide, a second annular portion comprising titanium nitride radially inward of the first annular portion, a third annular portion comprising TiOₓSi_{y}N_{z} radially inward of the second annular portion, where the x is 1.5 to 2.2, the y is 0.05 to 0.3, and the z is 0.05 to 0.3, and a fourth annular portion comprising the TiOₓSi_{y}N_{z} radially inward of the third annular portion, with the x being greater in the fourth annular portion than in the third annular portion.

In some embodiments, a capacitor comprises a first capacitor electrode, a second capacitor electrode, and a capacitor insulator between the first and second capacitor electrodes. The storage-node electrode comprises a container-like shape comprising an axis. In a cross-section that is through and elongated along the axis, the storage-node electrode comprises a radially-outermost conductive surface comprising a first conductive material and a radially-innermost conductive surface comprising a second conductive material that is of different composition from that of the first conductive material.

In compliance with the statute, the subject matter disclosed herein has been described in language more or less specific as to structural and methodical features. It is to be understood, however, that the claims are not limited to the specific features shown and described, since the means herein disclosed comprise example embodiments. The claims are thus to be afforded full scope as literally worded, and to be appropriately interpreted in accordance with the doctrine of equivalents.

1. Memory circuitry comprising:
vertically-stacked memory cells individually comprising a horizontal transistor and a capacitor electrically coupled therewith, the capacitor and horizontal transistor being horizontally spaced relative one another along an axis; the capacitor comprising a storage-node electrode, a common electrode that is common to a plurality of the capacitors of the memory cells, and a capacitor insulator between the storage-node and common electrodes; and
the storage-node electrode comprising a sideways container-like shape that faces horizontally away from the horizontal transistor in a first vertical cross-section that is through and horizontally-elongated along the axis; in a second vertical cross-section that is through and orthogonal to the axis, the storage-node electrode comprising:
a radially-outermost conductive surface comprising a first conductive material; and
a radially-innermost conductive surface comprising a second conductive material that is of different composition from that of the first conductive material.

2. The memory circuitry of claim 1 wherein the container-like shape in the first vertical cross-section comprises vertically opposing horizontal walls and a base vertically between the walls, the base in the first vertical cross-section comprising an outermost surface relative the container-like shape that comprises a third conductive material comprising a composition that is different from those of each of the first and second conductive materials.

3. The memory circuitry of claim 1 wherein the storage-node electrode comprises:
a first annular portion comprising the radially-outermost conductive surface;
a second annular portion radially inward of the first annular portion;
a third annular portion radially inward of the second annular portion; and a fourth annular portion radially inward of the third annular portion and comprising the radially-innermost conductive surface, the second and third annular portions being of different compositions relative one another and relative the first and second conductive materials.

4. The memory circuitry of claim 3 wherein the container-like shape in the first vertical cross-section comprises vertically opposing horizontal walls and a base vertically between the walls, the base in the first vertical cross-section comprising an outermost surface relative the container-like shape that comprises a third conductive material comprising a composition that is different from those of each of the first and second conductive materials.

5. The memory circuitry of claim 4 wherein the third conductive material is that of the second annular portion.

6. The memory circuitry of claim 5 wherein the base comprises the same materials as the second, third, and fourth annular portions.

7. Memory circuitry comprising:
vertically-stacked memory cells individually comprising a horizontal transistor and a capacitor electrically coupled therewith, the capacitor and horizontal transistor being horizontally spaced relative one another along an axis; the capacitor comprising a storage-node electrode, a common electrode that is common to a plurality of the capacitors of the memory cells, and a capacitor insulator between the storage-node and common electrodes; and
the storage-node electrode comprising a sideways container-like shape that faces horizontally away from the horizontal transistor in a first vertical cross-section that is through and horizontally-elongated along the axis; in a second vertical cross-section that is through and orthogonal to the axis, the storage-node electrode comprising:
a first annular portion comprising titanium oxide;
a second annular portion comprising titanium nitride radially inward of the first annular portion;
a third annular portion comprising TiOₓSi_{y}N_{z} radially inward of the second annular portion, where the x is 1.5 to 2.2, the y is 0.05 to 0.3, and the z is 0.05 to 0.3; and
a fourth annular portion comprising the TiOₓSi_{y}N_{z} radially inward of the third annular portion, the x being greater in the fourth annular portion than in the third annular portion.

8. The memory circuitry of claim 7 wherein the storage-node electrode comprises a radially-outermost conductive surface, the first annular portion comprising the radially-outermost conductive surface.

9. The memory circuitry of claim 7 wherein the storage-node electrode comprises a radially-innermost conductive surface, the fourth annular portion comprising the radially-innermost conductive surface.

10. The memory circuitry of claim 7 wherein,
the storage-node electrode comprises a radially-outermost conductive surface, the first annular portion comprising the radially-outermost conductive surface; and
the storage-node electrode comprises a radially-innermost conductive surface, the fourth annular portion comprising the radially-innermost conductive surface.

11. The memory circuitry of claim 7 wherein the container-like shape in the first vertical cross-section comprises vertically opposing horizontal walls and a base vertically between the walls, the base in the first vertical cross-section comprising an outermost surface comprising titanium nitride.

12. The memory circuitry of claim 11 wherein the base comprises the same materials as the second, third, and fourth annular portions.

13. The memory circuitry of claim 7 wherein at least the x varies in at least one of the third and fourth annular portions.

14. The memory circuitry of claim 13 wherein the x varies in at least the fourth annular portion.

15. The memory circuitry of claim 14 wherein the x increases in the fourth annular portion moving radially outward from the axis.

16. The memory circuitry of claim 14 wherein the x varies in the third annular portion.

17. The memory circuitry of claim 14 wherein the y is constant in the third annular portion and increases in the fourth annular portion moving radially outward from the axis.

18. A capacitor comprising:
a first capacitor electrode, a second capacitor electrode, and a capacitor insulator between the first and second capacitor electrodes; and
the storage-node electrode comprising a container-like shape comprising an axis; in a cross-section that is through and elongated along the axis, the storage-node electrode comprising:
a radially-outermost conductive surface comprising a first conductive material; and
a radially-innermost conductive surface comprising a second conductive material that is of different composition from that of the first conductive material.

19. The capacitor of claim 18 wherein the container-like shape in the cross-section comprises opposing walls and a base between the walls, the base in the cross-section comprising an outermost surface relative the container-like shape that comprises a third conductive material comprising a composition that is different from those of each of the first and second conductive materials.

20. The capacitor of claim 18 wherein the storage-node electrode comprises:
a first annular portion comprising the radially-outermost conductive surface;
a second annular portion radially inward of the first annular portion;
a third annular portion radially inward of the second annular portion; and a fourth annular portion radially inward of the third annular portion and comprising the radially-innermost conductive surface, the second and third annular portions being of different compositions relative one another and relative the first and second conductive materials.

21. The capacitor of claim 20 wherein the container-like shape in the cross-section comprises opposing walls and a base between the walls, the base in the cross-section comprising an outermost surface relative the container-like shape that comprises a third conductive material comprising a composition that is different from those of each of the first and second conductive materials.

22. The capacitor of claim 21 wherein the third conductive material is that of the second annular portion.

23. The capacitor of claim 22 wherein the base comprises the same materials as those of the second, third, and fourth annular portions.

24. The capacitor of claim 20 wherein,
the first annular portion comprises titanium oxide;
the second annular portion comprises titanium nitride;
the third annular portion comprises TiOₓSi_{y}N_{z} where the x is 1.5 to 2.2, the y is 0.05 to 0.3, and the z is 0.05 to 0.3; and
the fourth annular portion comprises the TiOₓSi_{y}N_{z} the x being greater in the fourth annular portion than in the third annular portion.

25. The capacitor of claim 24 wherein at least the x varies in at least one of the third and fourth annular portions.

26. The capacitor of claim 24 wherein the x varies in at least the fourth annular portion.

27. The capacitor of claim 26 wherein the x increases in the fourth annular portion moving radially outward from the axis.

28. The capacitor of claim 26 wherein the x varies in the third annular portion.

29. The capacitor of claim 26 wherein the y is constant in the third annular portion and increases in the fourth annular portion moving radially outward from the axis.
